(19) United States
(12) Patent Application Publication
(10) Pub. No.: US 2009/0011602 A1
(43) Pub. Date: Jan. 8, 2009

(54) Film Forming Method of Amorphous Carbon Film and Manufacturing Method of Semiconductor Device Using the Same

(75) Inventors: Toshihisa Nozawa, Hyogo (JP); Hiraku Ishikawa, Miyagi (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/280,413

(22) PCT Filed: Feb. 23, 2007
(86) PCT No.: PCT/JP2007/053432

§ 371 Date: Aug. 22, 2008

(30) Foreign Application Priority Data
Feb. 24, 2006 (JP) 2006-048312

(51) Int. Cl. H01L 21/311

(52) U.S. Cl. 438/694; 257/E21.249

(57) ABSTRACT

Disclosed is a film forming method of an amorphous carbon film, including: disposing a substrate in a processing chamber; supplying a processing gas containing carbon, hydrogen and oxygen into the processing chamber; and decomposing the processing gas by heating the substrate in the processing chamber and depositing the amorphous carbon film on the substrate.

### TECHNICAL FIELD

The present invention relates to a film forming method of an amorphous carbon film suitable to be used as a mask or the like when manufacturing a semiconductor device, and also relates to a method for manufacturing a semiconductor device by using the film forming method.

### BACKGROUND ART

In a manufacturing process of a semiconductor device, plasma etching has been performed to form a circuit pattern by using a resist patterned by a photolithography technology as a mask. In the 45 nm CD (Critical Dimension) generation, an ArF resist has been used as a mask to keep up with miniaturization, but the ArF resist has a disadvantage of low plasma resistance. As a way to resolve this problem, there has also been employed a method called a dry development using a multi-layer mask which is formed by laminating a SiO₂ film and a plasma-resistant resist underneath the ArF resist.

In the miniaturization generation after the 45 nm generation, the film thickness of the ArF resist is reduced to 200 nm, so that this thickness serves as a basis of the dry development. There are investigated a film thickness of SiO₂ capable of being plasma-etched by using the resist film of such thickness and a film thickness of the lower resist capable of being plasma-etched by using the SiO₂ of the film thickness, and thus the result shows that the limit of the latter is 300 nm. However, when the lower resist has that thickness, it is impossible to obtain a sufficient plasma resistance with respect to the film thickness of an etching target, thus resulting in a failure to accomplish an etching with a high precision. For this reason, there has been a demand for a film having a higher etching resistance as an alternative to the lower resist.

Meanwhile, Patent Document 1 (Japanese Patent Laid-open Application No. 2002-12972) discloses a method of using an amorphous carbon film, which is deposited by CVD (Chemical Vapor Deposition) while using a hydrocarbon gas and an inert gas, as a substitute for the SiO₂ film in the multi-layer resist structure or as an anti-reflection film. Here, an attempt to use the amorphous carbon film for the above-mentioned purpose is considered.

In Patent Document 1, a temperature for forming an amorphous carbon film is described to range from 100 to 500° C. However, it was proved that the amorphous carbon film formed in this temperature range does not have a sufficient etching resistance when it is used for the above-mentioned purpose. Further, based on the disclosure in Patent Document 1, it was also proved that a temperature as high as about 600° C. is required to obtain an amorphous carbon film having a sufficient resistance to be used for the aforementioned purpose. However, such a high temperature can not be applied to a back-end process using a Cu wiring.

### DISCLOSURE OF THE INVENTION

In view of the foregoing, the present invention is conceived to effectively solve the problems. An object of the present invention is to provide a method for forming a highly plasma resistant amorphous carbon film at a low temperature and a method for manufacturing a semiconductor device by using the film forming method.

The present invention is directed to a film forming method of an amorphous carbon film, including: disposing a substrate in a processing chamber; supplying a processing gas containing carbon, hydrogen and oxygen into the processing chamber; and decomposing the processing gas by heating the substrate in the processing chamber and depositing the amorphous carbon film on the substrate.

In accordance with the present invention, since a processing gas containing oxygen as well as carbon and hydrogen is employed, a reactivity is high during film formation and a hard carbon network can be formed at a relatively low temperature, thereby forming an amorphous carbon film having a high etching resistance. Further, it is possible to obtain a satisfactory etching profile with a high selectivity with respect to an underlying layer by etching an etching target film while using the amorphous carbon film obtained by this method as an etching mask. In particular, by using the amorphous carbon film obtained by the method of the present invention in lieu of a underlayer resist film in a conventional multi-layer resist, it is possible to more satisfactorily etch the etching target film and also possible to provide a great advantage in manufacturing the semiconductor device.

It is desirable that a ratio C:O between the number of carbon atoms and the number of oxygen atoms in the processing gas is set to be about 3:1 to 5:1. Further, it is desirable that a ratio C:H between the number of carbon atoms and the number of hydrogen atoms in the processing gas is set to be about 1:1 to 1:2.

Further, it is desirable that the processing gas containing the carbon, the hydrogen and the oxygen includes a gaseous mixture of a hydrocarbon gas and an oxygen-containing gas. In this case, for example, the hydrocarbon gas is at least one of C₂H₂O, C₄H₆ and C₆H₆.

Further, it is desirable that the processing gas containing the carbon, the hydrogen and the oxygen includes a gas containing carbon, hydrogen and oxygen in a molecule. In this case, for example, the gas containing the carbon, the hydrogen and the oxygen in the molecule is at least one of C₄H₄O and C₄H₈O.

Further, it is desirable that a temperature of the substrate is equal to or below about 400° C. in the step of depositing the amorphous carbon film on the substrate.

Further, it is desirable that the processing gas is converted into plasma in the step of depositing the amorphous carbon film on the substrate.

Further, the present invention is related to a manufacturing method of a semiconductor device, including: forming an etching target film on a substrate; forming an amorphous carbon film on the etching target film according to one of the above-described methods; forming an etching pattern on the amorphous carbon film; and forming a specific structure by etching the etching target film while using the amorphous carbon film as an etching mask.

Further, the present invention is directed to a manufacturing method of a semiconductor device, including: forming an etching target film on a substrate; forming an amorphous carbon film on the etching target film according to one of the above-described methods; forming a Si-based thin film on the amorphous carbon film; forming a photoresist film on the Si-based thin film; patterning the photoresist film; etching the Si-based thin film by using the photoresist film as an etching mask; transferring the pattern of the photoresist film by etching the amorphous carbon film while using the Si-based thin film as an etching mask; and etching the etching target film by using the amorphous carbon film as a mask.

Furthermore, the present invention provides a computer-readable storage medium for storing therein software for executing a control program in a computer, wherein, when executed, the control program controls a film forming apparatus to perform one of the above-described methods.

### BRIEF DESCRIPTION OF THE DRAWINGS

FIG. 1 illustrates a schematic cross-sectional view showing an example of a film forming apparatus which is applicable to a film forming method of an amorphous carbon film in accordance with an embodiment of the present invention;

FIG. 2 shows a cross-sectional view of a structure for manufacturing a semiconductor device by using an amorphous carbon film obtained by the film forming method in accordance with the embodiment of the present invention;

FIG. 3 illustrates a cross-sectional view showing a state in which a SiO₂ film underneath a patterned ArF resist is etched by using the patterned ArF resist as a mask in the structure of FIG. 2;

FIG. 4 provides a cross-sectional view showing a state in which the amorphous carbon film underneath the patterned SiO₂ film is etched by using the patterned SiO₂ film as a mask in the structure of FIG. 3;

FIG. 5 offers a cross-sectional view showing a state in which an underlying etching target film is etched by using the patterned amorphous carbon film as a mask; and

FIG. 6 shows a view of an electron diffraction image of the amorphous carbon film obtained in the embodiment of the present invention.

### BEST MODE FOR CARRYING OUT THE INVENTION

Hereinafter, embodiments of the present invention will be explained in detail with reference to the accompanying drawings.

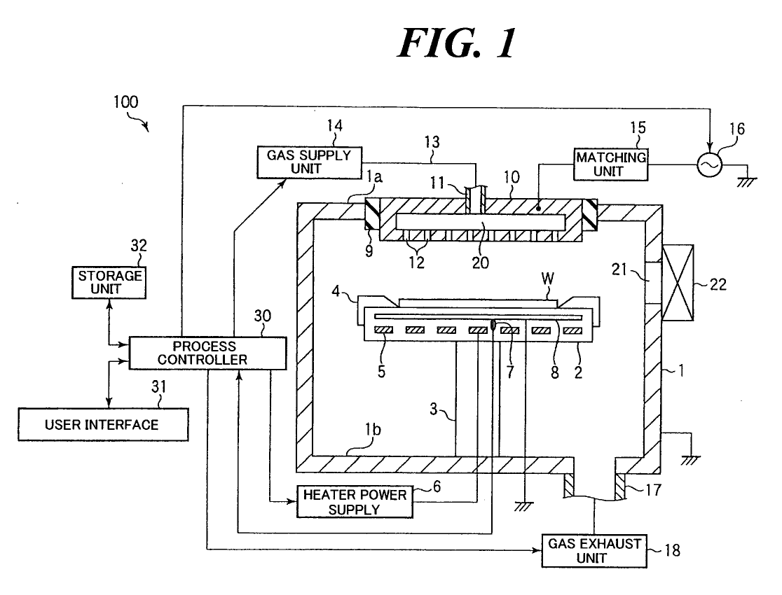

FIG. 1 illustrates a schematic cross-sectional view of an example of a film forming apparatus which can be applied to a film forming method of an amorphous carbon film in accordance with an embodiment of the present invention. The film forming apparatus 100 typically has a substantially cylindrical chamber 1.

A susceptor 2 for horizontally supporting a wafer W, which is a target object to be processed, is installed within the chamber 1. The susceptor 2 is supported by a cylindrical supporting member 3 installed in a central bottom portion within the chamber 1. A guide ring 4 for guiding the wafer W is installed at an outer periphery portion of the susceptor 2. Further, a heater 5 is embedded in the susceptor 2 to heat the wafer W up to a specific temperature by a power supplied from a heater power supply 6. A thermocouple 7 is also embedded in the susceptor 2. The output of the heater 5 is controlled based on a detection signal of the thermocouple 7. An electrode 8 is also buried in the susceptor 2 in the vicinity of the surface thereof, and the electrode 8 is grounded. Further, three wafer supporting pins (not shown) for supporting and lifting up and down the wafer W are installed in the susceptor 2 so that they can be projected from and retracted into the surface of the susceptor 2.

A shower head 10 is installed at a ceiling wall la of the chamber 1 via an insulating member 9. The shower head 10 is formed in a cylindrical shape and has a gas diffusion space 20 therein. Further, a gas inlet opening 11 for introducing a processing gas is provided in a top surface of the shower head 10, and a plurality of gas injection openings 12 are provided in a bottom surface thereof. The gas inlet opening 11 of the shower head 10 is connected to a gas supply unit 14 for supplying the processing gas for forming an amorphous carbon film through a gas pipe 13.

The shower head 10 is connected to a high frequency power supply 16 via a matching unit 15, so that a high frequency power is supplied to the shower head 10 from the high frequency power supply 16. By supplying the high frequency power from the high frequency power supply unit 16, the gas introduced into the chamber 1 through the shower head 10 can be converted into plasma.

A gas exhaust pipe 17 is installed in a bottom wall 1b of the chamber 1. The gas exhaust pipe 17 is connected to a gas exhaust unit 18 including a vacuum pump. By operating the gas exhaust unit 18, the inside of the chamber 1 can be depressurized to a specific vacuum level. Installed in a side wall of the chamber 1 are a transfer port 21 through which loading and unloading of the wafer W is performed; and a gate valve 22 for opening and closing the transfer port 21.

The components of the film forming apparatus 100 such as the heater power supply 6, the gas supply unit 14, the high frequency power supply 16, the gas exhaust unit 18 and the like are connected to and controlled by a process controller 30 including a CPU and a peripheral circuit thereof.

Further, the process controller 30 is connected to a user interface 31 including a keyboard with which a process manager inputs a command for managing the film forming apparatus 100, a display for visualizing and displaying an operational status of the film forming apparatus 100, and the like. Further, the process controller 30 is connected to a storage unit 32 storing therein control programs to be used in realizing various processes performed by the film forming apparatus 100 under the control of the process controller 30, and recipes, i.e., programs to be used in operating each component of the film forming apparatus 100 according to processing conditions.

The recipes may be stored in a hard disk or a semiconductor memory, or they can also be stored in a portable storage medium such as a CD-ROM, a DVD or the like so as to be set in a specific position of the storage unit 32. Alternatively, it is possible to properly transmit the recipes from another apparatus through, for example, a dedicated line. Further, a necessary recipe is retrieved from the storage unit 32 in response to an instruction from the user interface 31 and is executed by the process controller 30, whereby a desired process is performed in the film forming apparatus 100 under control of the process controller 30.

Hereinafter, an embodiment of the amorphous carbon film forming method, which is performed by using the above-described film forming apparatus 100, will be explained.

First, a wafer W is transferred into the chamber 1 and mounted on the susceptor 2. While supplying a plasma generating gas, e.g., an Ar gas, into the chamber 1 from the gas supply unit 14 through the gas pipe 13 and the shower head 10, the inside of the chamber 1 is exhausted by the gas exhaust unit 18 and maintained in a depressurized state. Further, the susceptor 2 is heated by the heater 5 to a specific temperature equal to or less than about 400° C. Further, as the high frequency power is applied onto the shower head 10 by the high frequency power supply 16, a high frequency electric field is generated between the shower head 10 and the electrode 8, and the plasma generating gas is converted into plasma.

In this state, a processing gas containing carbon, hydrogen and oxygen for forming an amorphous carbon film is introduced into the chamber 1 from the gas supply unit 14 through the gas pipe 13 and the shower head 10.

Subsequently, the processing gas is excited by the plasma in the chamber 1 and decomposed by being heated on the wafer W. As a result, the amorphous carbon film having a hard network structure therein is deposited on the surface of the wafer W.

In the disclosure of Patent Document 1, the hydrocarbon gas and the inert gas are used as a processing gas for forming an amorphous carbon film. However, from the knowledge and information of inventors of the present application, it is seen that under this condition, a formation of a carbon network in the amorphous carbon film progresses slowly, and the amorphous carbon film formed at a low temperature of about 400° C. or below still has many structurally weak portions and resultantly becomes to have a low etching resistance. Here, though it is possible to strengthen the structure to some extent and improve the etching resistance by increasing the film forming temperature, application to a back-end process becomes difficult in such case.

In contrast, in the embodiment of the present invention, oxygen as well as carbon and hydrogen constituting a hydrocarbon gas is used. This composition improves reactivity considerably, so that even at a low temperature of about 400° C. or below, it is possible to obtain an amorphous carbon film having a hard carbon network without having structurally weak film portions.

As for the processing gas containing the carbon, the hydrogen and the oxygen, it is desirable to set a ratio C:O between the number of carbon atoms and the number of oxygen atoms in the processing gas to be in the range of 3:1 to 5:1. Within this ratio range, it is possible to control the reactivity appropriately, thus obtaining a more desirable film.

Further, it is desirable to set a ratio C:H between the number of carbon atoms and the number of hydrogen atoms in the processing gas to be about 1:1 to 1:2. A compound gas having a ratio of C less than this range does not exist for practical use. Meanwhile, if the ratio of H exceeds this range, it is difficult to form a hard carbon network.

The processing gas containing the carbon, the hydrogen and the oxygen can be, typically, a gaseous mixture of a hydrocarbon gas and an oxygen-containing gas. To be specific, the hydrocarbon gas can be C₂H₂ (acetylene), C₄H₆ (butyne (including 1-butyne and 2-butyne)) and C₆H₆ (benzene), and these gases can be used individually or in combinations. Further, an O₂ gas can be used properly as the oxygen-containing gas, and it is also possible to use an ether compound such as CH₃—O—CH₃ (dimethylether) as the oxygen-containing gas.

Another example of the processing gas containing the carbon, the hydrogen and the oxygen can be a gas containing a gas having carbon, hydrogen and oxygen in a molecule. As examples of such gas, C₄H₄O (furan) and C₄H₈O (tetrahydrofuran) can be considered, and these gases can be used individually or in combination.

Besides the gas containing the carbon, the hydrogen and the oxygen, an inert gas such as an Ar gas or the like may also be included in the processing gas. In case of using a 300 mm wafer, it is desirable to set the flow rate of the Ar gas to be about 20˜100% of the flow rate of the gas including the carbon, the hydrogen and the oxygen. Though the flow rates of the inert gas and the gas containing the carbon, the hydrogen and the oxygen vary depending the kind of the gases, it is desirable to set their flow rates to be about 250˜350 mL/mim (sccm). Further, it is desirable to set the internal pressure of the chamber to be about 6.65 Pa (50 mTorr) or below during film formation.

It is desirable to set a wafer temperature (film forming temperature) during the formation of the amorphous carbon film to be about 400° C. or below; and, more desirably, about 100˜300° C.; and, most desirably, about 200° C. or thereabout. As stated above, if the temperature is equal to or below about 400° C., application to a back-end process using a Cu wiring is possible. In accordance with the embodiment of the present invention, it is possible to form, even at such a relatively low temperature, an amorphous carbon film having a high etching resistance which is required for a lowermost layer of a multi-layer resist.

The frequency and the power of the high frequency power applied to the shower head 10 can be properly set according to a required degree of reactivity. By applying the high frequency power in this way, the high-frequency electric field is generated within the chamber 1, so that the processing gas can be converted into plasma, and the formation of the amorphous carbon film can be realized by plasma CVD. Since the gas converted into plasma has a high reactivity, it is possible to lower the film forming temperature. Further, it is possible to use not only a capacitively coupled plasma source using the high frequency power as stated above but also an inductively coupled plasma source. Further, it is possible to generate plasma by introducing a microwave into the chamber 1 through a waveguide and an antenna. Furthermore, even a plasma generation is not essential. It is possible to form the amorphous carbon film by thermal CVD when the reactivity is sufficiently high.

The amorphous carbon film formed by the above-described method has a hard carbon network and a high etching resistance, as stated above, so that it is suitable to be used as the lowermost layer of the multi-layer resist. Further, since the amorphous carbon film formed by the above-described method has a light absorption coefficient of about 0.1˜1.0 at a wavelength of about 250 nm or below, it is also suitable to be used as an anti-reflection film.

Hereafter, a method for manufacturing a semiconductor device by using the amorphous carbon film formed as described above will be explained.

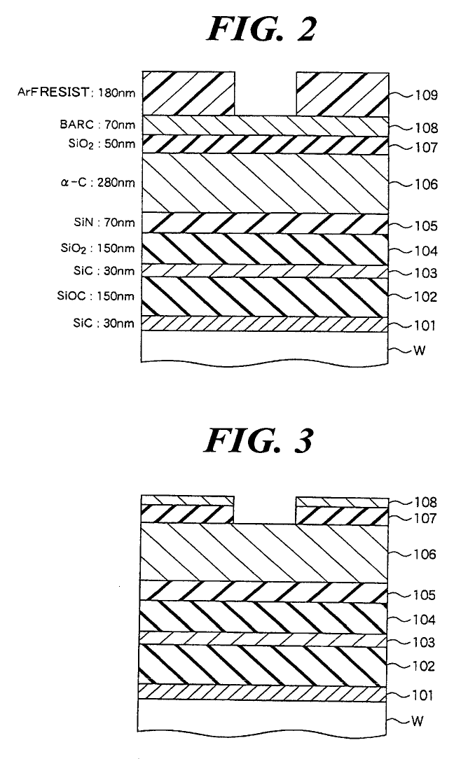

As illustrated in FIG. 2, formed, as an etching target film, on a semiconductor wafer W (Si substrate) is a laminated film made up of a SiC film 101, a SiOC film (Low-k film) 102, a SiC film 103, a SiO₂ film 104, and a SiN film 105, and an amorphous carbon (α-C) film 106 is formed on the laminated film according to the above-described method. Further, a SiO₂ film 107, a BARC film (anti-reflection film) 108 and an ArF resist film 109 are formed thereon in sequence, wherein the ArF resist film 109 is patterned by a photolithography process. By the above-mentioned processes, a multi-layer etching mask is formed.

Here, the thickness of the ArF resist film 109 is about 200 nm or below, for example, about 180 nm; the thickness of the BARC film 108 is in the range of about 30 to 100 nm, for example, about 70 nm; the thickness of the SiO₂ film 107 is in the range of about 10 to 100 nm, for example, about 50 nm; and the thickness of the amorphous carbon film 106 is in the range of about 100 to 800 nm, for example, about 280 nm. Further, as for the thickness of the etching target film, the SiC film 101 is about 30 nm; the SiOC film (Low-k film) 102 is about 150 nm; the SiC film 103 is about 30 nm; the SiO₂ film 104 is about 150 nm; and the SiN film 105 is about 70 nm. Here, it is possible to use another Si-based thin film such as SiOC, SiOH, SiCN, SiCNH, or the like, instead of the Sio₂ film 107.

In this state, the BARC film 108 and the Sio₂ film 107 are plasma-etched by using the ArF resist film 109 as a mask, so that the pattern of the ArF resist film 109 is transferred to the SiO₂ film 107, as illustrated in FIG. 3. At this time, since the ArF resist film 109 has a low etching resistance, it is removed by the etching, and a part of the BARC film 108 is also etched.

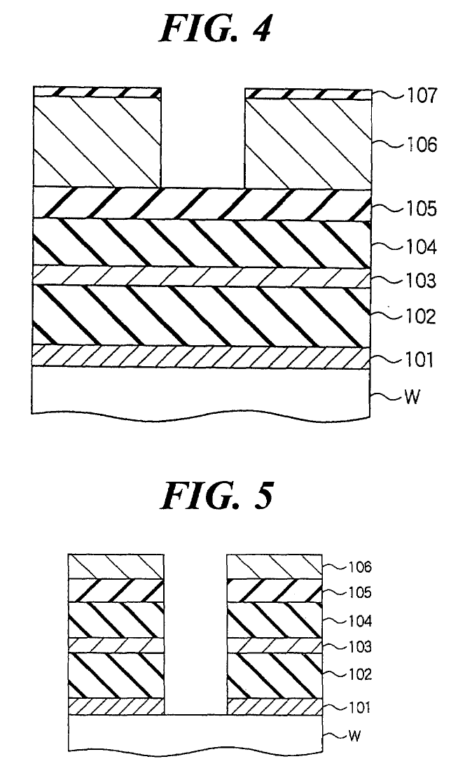

Subsequently, as illustrated in FIG. 4, the amorphous carbon film 106 is etched by using the SiO₂ film 107 as an etching mask, so that the pattern of the ArF resist film 109 is transferred to the amorphous carbon film 106. Here, the amorphous carbon film 106 formed in accordance with the above-described method has a high etching resistance. Accordingly, the amorphous carbon film 106 is etched in a good etching shape, that is, the pattern of the ArF resist film 109 is accurately transferred to the amorphous carbon film 106.

Then, as illustrated in FIG. 5, the SiN film 105, the SiO₂ film 104, the SiC film 103, the SiOC film 102 and the SiC film 101 are plasma-etched in sequence by using the amorphous carbon film 106 as an etching mask. Here, since the amorphous carbon film 106 formed in accordance with the above-described method has a high etching resistance, it is possible to etch the underlying etching target film with a high selectivity. That is, while the etching target film is being etched, the amorphous carbon film 106 sufficiently remains as an etching mask, so that it is possible to obtain a good etching shape in the etching target film without suffering a pattern distortion.

When the etching process is completed, the SiO₂ film 107 has already been removed. Further, the remaining amorphous carbon film 106 can be removed comparatively easily by ashing using a H₂ gas/a N₂ gas.

Subsequently, the properties and the etching resistance of the amorphous carbon film formed in accordance with the present invention were actually evaluated.

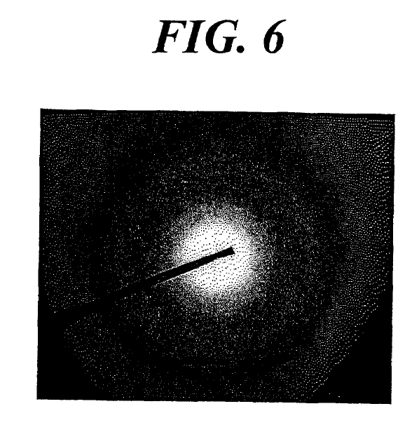

Here, a C₄H₄O (furan) gas is used as the gas containing the carbon, the hydrogen and the oxygen, and a film is deposited on a wafer by the plasma CVD method at a substrate temperature of about 200° C. FIG. 6 shows an electron diffraction image in a center portion of the obtained film. As can be seen in FIG. 6, since a diffraction spot indicating a crystalline orientation is not found, it can be confirmed that the obtained film is an amorphous carbon film.

Then, the etching resistance of the amorphous carbon film obtained as described above was compared with the etching resistance of a thermal oxide film (SiO₂) and the etching resistance of a g-line photoresist film used as a lower resist. The etching process was carried out in a parallel plate type plasma etching apparatus by using a C₅F₈ gas, an Ar gas or an O₂ gas as an etching gas.

As a result, an etching rate of each film is obtained as follows:

SiO₂ film: 336.9 nm/min;

photoresist film: 53.3 nm/min; and

amorphous carbon film: 46.4 nm/min.

That is, the selectivities of the photoresist film and the amorphous carbon film against the Sio₂ film are 6.3 and 7.3, respectively. From this result, it can be confirmed that the amorphous carbon film formed in accordance with the method of the present invention has an advantage over the conventional photoresist film.

The present invention is not limited to the above-described embodiments, but can be modified in various ways. For example, in the above-described embodiments, though the gaseous mixture of the hydrocarbon gas and the oxygen-containing gas or the gas containing the carbon, the hydrogen and the oxygen in the molecule are given as examples of the processing gas for forming the amorphous carbon film, the processing gas is not limited thereto. Further, in the above-described embodiments, though the amorphous carbon film formed in accordance with the method of the present invention is applied to the lowermost layer of the multi-layer resist during the dry development, its application is not limited thereto. For example, it is also possible to use the amorphous carbon film as an etching mask having a function of an anti-reflection film by forming it directly under a typical photoresist film. Besides, the amorphous carbon film can be used in various other ways.

Furthermore, in the above-described embodiments, though the semiconductor wafer is exemplified as the target substrate, the kind of the target substrate is not limited thereto. For example, the present invention can be applied to a glass plate for use in a flat panel display (FPD) represented by a liquid crystal display (LCD), or the like.

What is claimed is:

1. A film forming method of an amorphous carbon film, comprising:
disposing a substrate in a processing chamber;
supplying a processing gas containing carbon, hydrogen and oxygen into the processing chamber; and
decomposing the processing gas by heating the substrate in the processing chamber and depositing the amorphous carbon film on the substrate.

2. The method of claim 1, wherein a ratio C:O between the number of carbon atoms and the number of oxygen atoms in the processing gas is set to be about 3:1 to 5:1.

3. The method of claim 1, wherein a ratio C:H between the number of carbon atoms and the number of hydrogen atoms in the processing gas is set to be about 1:1 to 1:2.

4. The method of claim 1, wherein the processing gas containing the carbon, the hydrogen and the oxygen includes a gaseous mixture of a hydrocarbon gas and an oxygen-containing gas.

5. The method of claim 4, wherein the hydrocarbon gas is at least one of C₂H₂O, C₄H₆ and C₆H₆.

6. The method of claim 1, wherein the processing gas containing the carbon, the hydrogen and the oxygen includes a gas containing carbon, hydrogen and oxygen in a molecule.

7. The method of claim 6, the gas containing the carbon, the hydrogen and the oxygen in the molecule is at least one of C₄H₄O and C₄H₈O.

8. The method of claim 1, wherein a temperature of the substrate is equal to or below about 400 in the step of depositing the amorphous carbon film on the substrate.

9. The method of claim 1, wherein the processing gas is converted into plasma in the step of depositing the amorphous carbon film on the substrate.

10. A manufacturing method of a semiconductor device, comprising:
forming an etching target film on a substrate;
forming an amorphous carbon film on the etching target film according to a method as claimed in claim 1;
forming an etching pattern on the amorphous carbon film; and
forming a specific structure by etching the etching target film while using the amorphous carbon film as an etching mask.

11. A manufacturing method of a semiconductor device, comprising:
forming an etching target film on a substrate;
forming an amorphous carbon film on the etching target film according to a method as claimed in claim 1;
forming a Si-based thin film on the amorphous carbon film;
forming a photoresist film on the Si-based thin film;
patterning the photoresist film;
etching the Si-based thin film by using the photoresist film as an etching mask;
transferring the pattern of the photoresist film by etching the amorphous carbon film while using the Si-based thin film as an etching mask; and
etching the etching target film by using the amorphous carbon film as a mask.

12. A computer-readable storage medium for storing therein software for executing a control program in a computer, wherein, when executed, the control program controls a film forming apparatus to perform a method as claimed in claim 1.
